(19) United States
(12) Patent Application Publication
(10) Pub. No.: US 2026/0209940 A1
(43) Pub. Date: Jul. 23, 2026

(54) METHODS OF FORMING AN N-DIPOLE STRUCTURE

(71) Applicant: ASM IP Holding B.V., Almere (NL)

(72) Inventors: Chunhai Yin, Leuven (BE); Andrea Illiberi, Gilbert, AZ (US); Rishabh Rastogi, Chandler, AZ (US); Ren-Jie Chang, Chandler, AZ (US); Fu Tang, Gilbert, AZ (US); Eric James Shero, Phoenix, AZ (US); Charles Dezelah, Helsinki (FI)

(21) Appl. No.: 19/453,231

(22) Filed: Jan. 20, 2026

Related U.S. Application Data
(60) Provisional application No. 63/748,075, filed on Jan. 22, 2025.

(51) Int. Cl. C23C 16/455; C23C 16/18; H10D 64/01; H10P 14/43

(52) U.S. Cl. CPC C23C 16/45553; C23C 16/18; H10D 64/01318; H10P 14/43

(57) ABSTRACT

Methods and systems for forming structure comprising an N-dipole shifting material layer are disclosed. Exemplary methods include providing a rare earth metal precursor to the reaction chamber for a precursor pulse and providing an alcohol reactant to the reaction chamber.

### CROSS-REFERENCE TO RELATED APPLICATIONS

This application is a nonprovisional of, and claims priority to and the benefit of, U.S. Provisional Patent Application No. 63/748,075, filed Jan. 22, 2025 and entitled “METHODS OF FORMING AN N-DIPOLE STRUCTURE,” which is hereby incorporated by reference herein.

### FIELD OF DISCLOSURE

The present disclosure generally relates to the field of semiconductor processing methods and systems. More particularly, the disclosure relates to methods and systems for forming structures that include a threshold voltage tuning layer.

### BACKGROUND OF THE DISCLOSURE

The scaling of semiconductor devices, such as, for example, complementary metal-oxide-semiconductor (CMOS) devices, has led to significant improvements in speed and density of integrated circuits. However, conventional device scaling techniques face significant challenges as device feature sizes continue to decrease.

For example, one challenge has been finding a suitable conducting material for use as a gate electrode in CMOS devices. Various gate materials might be used, such as, for example, a metal, such as a titanium nitride layer. However, in some cases, it may be difficult to obtain a desired work function using traditional gate electrode materials.

Accordingly, especially as critical dimensions of devices continue to decrease, improved methods for forming gate electrode materials are desired.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY OF THE DISCLOSURE

This summary may introduce a selection of concepts in a simplified form, which may be described in further detail below. This summary is not intended to necessarily identify key features or essential features of the claimed subject matter, nor is it intended to be used to limit the scope of the claimed subject matter.

Various embodiments of the present disclosure relate to methods of forming a structure, such as an N-dipole structure, to structures and devices formed using such methods, and to systems for performing the methods and/or for forming the structures and/or devices. The structures can be used in the formation of a variety of devices that are suitable for a variety of applications. For example, the structures can be used in the formation of a gate electrode in metal oxide semiconductor field effect transistors (MOSFETs).

In accordance with various examples of the disclosure, a method of forming an N-dipole structure is provided. An exemplary method includes providing a substrate within a reaction chamber of a reactor and depositing an N-dipole shifting material layer on the substrate using a cyclical deposition process. The N-dipole shifting material layer can be used to obtain a desired threshold voltage of the structure or a device formed using the structure. In accordance with examples of the disclosure, the step of depositing includes providing a rare earth metal precursor to the reaction chamber for a precursor pulse and providing an alcohol reactant to the reaction chamber. The alcohol reactant can be an alcohol of the formula ROH, where R is a substituted or unsubstituted alkyl group comprising 1 to 12 carbon atoms or is a substituted or unsubstituted aryl group comprising 6 to 10 carbon atoms. Use of an alcohol reactant, rather than a more traditional oxidant, such as H₂O, may be advantageous for a variety of reasons. For example, some materials (e.g., lanthanum oxide) used in the formation of N-dipole structures are hygroscopic. The hygroscopic nature of such materials can lead to process drift over time. To mitigate such effect, a process chamber can be coated. However, this can result in undesirable increase in production time. Additionally or alternatively, traditional oxidants, such as O₂, O₃, and H₂O, can cause undesired and/or uncontrolled oxidation of an underlying surface, such as silicon or silicon oxide, which can result in a thicker oxide layer than desired. Further, use of such traditional oxides can result in an effective oxide thickness penalty of about 1.2 Å, which is undesirable for dipole applications.

In accordance with various aspects of these embodiments, the (substituted or unsubstituted) alkyl group can include a straight chain, a branched chain, or a cyclic formation of carbon atoms. The alkyl group can include a substituted alkyl group that includes, for example, one or more atoms selected from the list of N, O, F, Si, S, or Cl. The substituted or unsubstituted alkyl group can include a carbon-carbon double bond and/or a carbon-carbon triple bond. By way of example, the substituted or unsubstituted alkyl group can be selected from one or more of methyl, ethyl, propyl, isopropyl, butyl, sec-butyl, isobutyl, tert-butyl, pentyl, 2-pentyl, 3-pentyl, tert-pentyl, cyclopentyl, hexyl, or cyclohexyl groups. The substituted or unsubstituted aryl group can include a phenyl group. In some cases, the substituted or unsubstituted aryl group includes a phenyl group with an (e.g., one) alkyl substituent. In accordance with some examples, the substituted or unsubstituted aryl group includes a toluyl group, a xylyl group, or a mesityl group. By way of particular examples, the alcohol reactant is or includes one or more of methanol, ethanol, 1-propanol, isopropanol, 1-butanol, 2-butanol, isobutanol, tert-butanol, 1-pentanol, 1-hexanol, cyclohexanol, or phenol.

In accordance with further examples of these embodiments, the rare earth metal precursor comprises one or more elements selected from the group consisting of Sc, Y, La, and Lu. In accordance with various aspects of these examples, the rare earth metal precursor comprises one or more cyclopentadienyl ligands. In accordance with additional aspects of these examples, the rare earth metal precursor comprises one or more amido ligands. In accordance with additional aspects of these examples, the rare earth metal precursor comprises one or more amidinate ligands. In accordance with additional aspects of these examples, the rare earth metal precursor comprises one or more alkoxide ligands. In accordance with additional aspects of these examples, the rare earth metal precursor comprises one or more enaminolate ligands. In accordance with additional aspects of these examples, the rare earth metal precursor comprises one or more diketonate ligands.

Structures formed using a method as described herein may be a dipole first structure. Alternatively, the structures can be a dipole middle or a dipole last structure.

Further described herein is a system comprising a reaction chamber, a rare earth metal precursor source, an alcohol reactant source, and a controller. The controller is configured to control gas flow into the reaction chamber to form a structure by means of a method as described herein.

These and other embodiments will become readily apparent to those skilled in the art from the following detailed description of certain embodiments having reference to the attached figures. The invention is not limited to any particular embodiments disclosed.

### BRIEF DESCRIPTION OF THE DRAWING FIGURES

A more complete understanding of the embodiments of the present disclosure may be derived by referring to the detailed description and claims when considered in connection with the following illustrative figures.

FIG. 1 illustrates a method in accordance with exemplary embodiments of the disclosure.

FIG. 2 illustrates a structure in accordance with exemplary embodiments of the disclosure.

FIG. 3 illustrates another structure in accordance with examples of the disclosure.

FIG. 4 illustrates a system in accordance with yet additional exemplary embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

The description of exemplary embodiments of methods, structures, devices and systems provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features. For example, various examples are set forth as exemplary embodiments. Unless otherwise noted, the examples or components thereof may be combined or may be applied separate from each other.

As set forth in more detail below, various embodiments of the disclosure provide methods of forming an N-dipole structure. The structures can be suitable for use as, for example, gate electrode structures. Exemplary methods can be used to, for example, form CMOS devices, or portions of such devices. This notwithstanding, and unless noted otherwise, the invention is not necessarily limited to such examples.

In this disclosure, a gas can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas, such as a rare gas. In some cases, the term precursor can refer to a compound that participates in the chemical reaction that produces another compound, and particularly to a compound that constitutes a film matrix or a main skeleton of a film. The term reactant can be used to refer to a gas that reacts with the precursor to form deposited material. In some cases, the term reactant can be used interchangeably with the term precursor.

As used herein, the term substrate can refer to any underlying material or materials that can be used to form, or upon which, a device, a circuit, or a film can be formed. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of examples, a substrate can include semiconductor material. The semiconductor material can include or be used to form one or more of a source, drain, and/or channel region of a device. The substrate can further include an interlayer dielectric (e.g., silicon oxide) and/or a high dielectric constant material layer overlying the semiconductor material. In this context, high dielectric constant material or high k dielectric material is material having a dielectric constant greater than the dielectric constant of silicon dioxide.

As used herein, the term film and/or layer can refer to any continuous or non-continuous structure and material, such as material deposited by the methods disclosed herein. For example, a film and/or layer can include two-dimensional materials, three-dimensional materials, nanoparticles, partial or full molecular layers or partial or full atomic layers or clusters of atoms and/or molecules. A film or layer may partially or wholly consist of a plurality of dispersed atoms on a surface of a substrate and/or embedded in a substrate and/or embedded in a device manufactured on that substrate. A film or layer may comprise material or a layer with pinholes and/or isolated islands. A film or layer may be at least partially continuous. A film or layer may be patterned, e.g., subdivided, and may be comprised in a plurality of semiconductor devices.

As used herein, a structure can be or include a substrate as described herein. Structures can include one or more layers overlying the substrate, such as one or more layers formed according to a method as described herein. Device portions can be or include structures.

The term deposition process as used herein can refer to the introduction of precursors (and/or reactants) into a reaction chamber to deposit a layer or material over a substrate. Cyclical deposition processes are examples of deposition processes.

The term cyclic deposition process or cyclical deposition process can refer to a sequential introduction of precursors (and/or reactants) into a reaction chamber to deposit a layer over a substrate and includes processing techniques, such as atomic layer deposition (ALD), cyclical chemical vapor deposition (cyclical CVD), and hybrid cyclical deposition processes that include an ALD component and a cyclical CVD component.

As used herein, the term purge can refer to a procedure in which an inert or substantially inert gas is provided to a reaction chamber in between two pulses of gases that might otherwise react with each other. For example, a purge, e.g., using an inert gas, such as a noble gas, may be provided between a precursor pulse and a reactant pulse to reduce gas phase interactions between the precursor and the reactant that might otherwise occur. It shall be understood that a purge can be effected either in time or in space, or both. For example, in the case of temporal purges, a purge step can be used, e.g., in the temporal sequence of providing a precursor to a reaction chamber, providing a purge gas to the reaction chamber, and providing a reactant or another precursor to the reaction chamber, wherein the substrate on which a layer is deposited does not move. In the case of spatial purges, a purge step can take the following form: moving a substrate from a first location to which a precursor is (e.g., continually) supplied, through a purge gas curtain, to a second location to which a reactant or other precursor is (e.g., continually) supplied.

Further, in this disclosure, any two numbers of a variable can constitute a workable range of the variable, and any ranges indicated may include or exclude the endpoints. Additionally, any values of variables indicated (regardless of whether they are indicated with the term about or not) may refer to precise values or approximate values and include equivalents, and may refer to average, median, representative, majority, or the like. For example, the term about can refer to +/−20, 10, 5, 2, or 1 percent of a value. Further, in this disclosure, the terms comprising, including, constituted by and having and their equivalents can refer independently to typically or broadly comprising, comprising, consisting essentially of, or consisting of in some embodiments.

In this disclosure, any defined meanings do not necessarily exclude ordinary and customary meanings, in some embodiments.

Described herein are methods of forming a structure including an N-dipole shifting material layer or threshold voltage tuning layer. As set forth in more detail below, exemplary methods provide techniques for providing desired growth rate and/or other properties of a deposited material layer. The material layers formed according to the present methods are highly advantageous, e.g., for the purpose of work function tuning, throughput, and/or cost of production.

Layers formed using a presently described method may be useful, for example, as gate stack work function tuning metals in MOSFETs. Additionally or alternatively, the material layers may be used in MIM metal electrodes and/or in VNAND contacts.

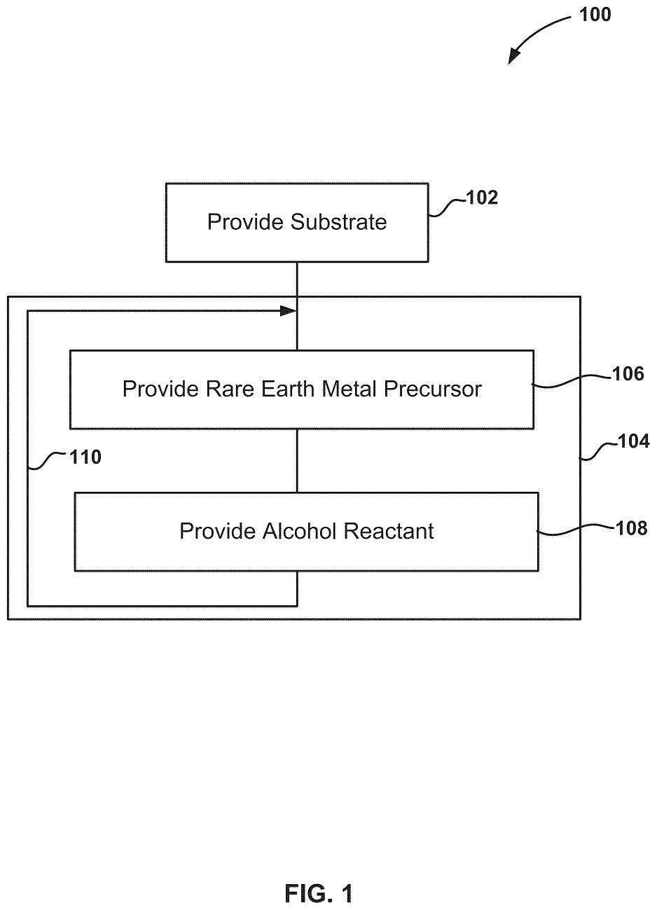

Turning now to the figures, FIG. 1 illustrates an exemplary method 100 in accordance with embodiments of the disclosure. As illustrated, method 100 includes the steps of providing a substrate (102) and depositing an N-dipole shifting material layer on the substrate (104). Although not separately illustrated, method 100 can include a drive-in anneal in some cases.

Method 100 can be used to form dipole first structures, in which the N-dipole shifting material layer is formed directly on an interlayer dielectric or a silicon oxide or a treated surface thereof, or dipole last structure, in which the N-dipole shifting material layer is formed directly on a high-k dielectric layer or treated surface thereof, or dipole middle structure.

During step 102, a substrate is provided within a reaction chamber. The reaction chamber used during step 102 can be or include a reaction chamber of a chemical vapor deposition reactor system configured to perform a cyclical deposition process. The reaction chamber can be a standalone reaction chamber or part of a cluster tool.

In accordance with examples of the disclosure, the substrate can comprise a surface comprising an oxide. The oxide can be, for example, a (e.g., deposited) silicon oxide or a metal oxide, such as a high dielectric constant metal oxide, such as hafnium oxide, zirconium oxide, hafnium zirconium oxide, hafnium silicate, or the like.

Step 102 can include heating the substrate to a desired deposition temperature within the reaction chamber. In some embodiments of the disclosure, step 102 includes heating the substrate to a temperature of less than 600° C. For example, in some embodiments of the disclosure, heating the substrate to a deposition temperature may comprise heating the substrate to a temperature between approximately 20° C. and approximately 100° C., about 200° C. and about 300° C., about 20° C. and about 400° C., or about 20° C. and about 600° C.

In addition to controlling the temperature of the substrate, a pressure within the reaction chamber may also be regulated. For example, in some embodiments of the disclosure, the pressure within the reaction chamber during step 102 may be less than 760 Torr or between 0.2 Torr and 760 Torr, about 1 Torr and 100 Torr, or about 1 Torr and 10 Torr.

During step 104, an N-dipole shifting material layer is deposited overlying the substrate surface. In accordance with examples of these embodiments, step 104 includes a cyclical deposition process. The cyclical process can include providing a rare earth metal precursor to the reaction chamber for a precursor pulse (106) and providing an alcohol reactant to the reaction chamber—e.g., for a reactant pulse (108).

Exemplary alcohol reactants provided during step 108 include an alcohol of the formula ROH, where R is a substituted or unsubstituted alkyl group comprising 1 to 12 carbon atoms or is a substituted or unsubstituted aryl group comprising 6 to 10 carbon atoms. The substituted or unsubstituted alkyl group can be or include a straight chain, a branched chain, or a cyclic formation of carbon atoms. The substituted or unsubstituted alkyl group can include one or more carbon-carbon double bonds and/or one or more carbon-carbon triple bonds. In these cases of substituted alkyl groups, the alkyl group can include, for example, one or more atoms selected from the list of N, O, F, Si, S, or Cl. By way of examples, the substituted or unsubstituted alkyl group can be selected from one or more of methyl, ethyl, propyl, isopropyl, butyl, sec-butyl, isobutyl, tert-butyl, pentyl, 2-pentyl, 3-pentyl, tert-pentyl, cyclopentyl, hexyl, and/or cyclohexyl groups. In accordance with further examples, the substituted or unsubstituted aryl group comprises a phenyl group. In some cases, the substituted or unsubstituted aryl group can include a phenyl group with a (e.g., one) (e.g., C1-C6 or C1-C4) alkyl substituent. In some cases, the substituted or unsubstituted aryl group includes a toluyl group, a xylyl group, or a mesityl group, any of which can include, for example, one or more independently selected C1-C4 alkyl groups. By way of particular examples, the alcohol reactant is or includes one or more of methanol, ethanol, 1-propanol, isopropanol, 1-butanol, 2-butanol, isobutanol, tert-butanol, 1-pentanol, 1-hexanol, cyclohexanol, or phenol.

A flowrate of the alcohol reactant to the reaction chamber can be between about 10 and about 5000 sccm. A duration of an alcohol reactant or reactant pulse to the reaction chamber can be between about 0.05 seconds and about 2 seconds or can be continuous through one or more deposition cycles.

In accordance with further examples, the rare earth metal precursor that is provided during step 106 includes an element selected from the rare earth metals, which can be defined to include elements from Group 3 of the periodic table and from the lanthanide series. In some cases, the rare earth metal precursor comprises an element selected from one or more elements selected from the group consisting of Sc, Y, La, Ce, Pr, Nd, Pm, Sm, Eu, Gd, Tb, Dy, Ho, Er, Tm, Yb, and Lu, such as Sc, Y, and La, or Lu.

In some embodiments, the rare earth metal precursor comprises one or more of the following ligand types.

Cyclopentadienyl ligands, examples of which include but are not limited to cyclopentadienyl (Cp), methylcyclopentadienyl (MeCp), ethylcyclopentadienyl (EtCp), n-propylcyclopentadientyl (nPrCp), isopropylcyclopentadienyl (iPrCp), n-butylcyclopentadienyl (nBuCp), sec-butycyclopentadienyl (sBuCp), isobutylcyclopentadienyl (iBuCp), tert-butylcyclopentadienyl (tBuCp), trimethylsilylcyclopentadienyl (TMSCp), pentamethylcyclopentadientyl (Cp*), 1,2,4-triisopropylcyclopentadienyl (iPr₃Cp), and 1,2,4-tri-tert-butylcyclopentadienyl (tBu₃Cp).

Amido ligands, examples of which include but are not limited to dimethylamido (NMe₂), diethylamido (NEt₂), ethylmethylamido (NEtMe), diisopropylamido (NiPr₂), tert-butylamino (NHtBu), and bis(trimethylsilyl)amido (N(SiMe₃)₂).

Amidinate ligands, examples of which include but are not limited to N,N′-₂iethylacetamidinate (Et₂AMD), N,N′-diisopropylacetamidinate (iPr₂AMD), N,N′-d₂isopropylformamidinate (iPr₂FMD), N,N′-di-tert-butylacetamidinate (tBu₂AMD), and N,N′-di-tert-butylformamidinate (tBu₂FMD).

Alkoxide ligands, examples of which include but are not limited to methoxide (OMe), ethoxide (OEt), isopropoxide (OiPr), tert-butoxide (OtBu), 1-methoxy-2-methyl-2-propoxide (mmp), 1-dimethylamino-2-propoxide (dmap), 1-dimethylamino-2-methyl-2-propoxide (dmamp), 1-ethylmethylamino-2-methyl-2-propoxide (emamp), 1-diethylamino-2-methyl-2-propoxide (deamp), 1-dimethylamino-2-methyl-2-butoxide (dmamb), 1-ethylmethylamino-2-methyl-2-butoxide (emamb), and 1-diethylamino-2-methyl-2-butoxide (deamb).

Enaminolate ligands, examples of which include but are not limited to 1-dimethylamino-3,3-dimethylbut-1-en-2-olate (dmadmb), 1-diethylamino-3,3-dimethylbut-1-en-2-olate (deadmb), 1-(N-pyrrolidinyl)-3,3-dimethylbut-1-en-2-olate (pydmb), 1-(N-piperidinyl)-3,3-dimethylbut-1-en-2-olate (pipdmb).

Diketonate ligands, examples of which include but are not limited to acetylacetonate (acac), 2,2,6,6-tetramethylheptane-3,5-dionate (thd), and 1,1,1,5,5,5-hexafluoropentane-2,5-dionate (hfac).

Specific examples of rare earth metal precursors suitable for use with various embodiments of method 100 include the following.

Scandium precursors: In some embodiments, the Sc precursor is selected from the following: ScCp₃, Sc(MeCp)₃, Sc(EtCp)₃, Sc(iPrCp)₃, Sc(acac)₃, Sc(thd)₃, Sc(N(SiMe₃)₂)₃, Sc(Et₂AMD)₃, Sc(iPr₂FMD)₃, Sc(iPr₂AMD)₃, Sc(tBu₂FMD)₃, Sc(tBu₂AMD)₃, ScCp₂(iPr₂FMD), Sc(MeCp)₂(iPr₂FMD), Sc(EtCp)₂(iPr₂FMD), Sc(iPrCp)₂(iPr₂FMD), ScCp₂(iPr₂AMD), Sc(MeCp)₂(iPr₂AMD), Sc(EtCp)₂(iPr₂AMD), and Sc(iPrCp)₂(iPr₂AMD).

Yttrium precursors: In some embodiments, the yttrium precursor is selected from the following: YCp₃, Y(MeCp)₃, Y(EtCp)₃, Y(iPrCp)₃, Y(tBuCp)₃, Y(thd)₃, Y(N(SiMe₃)₂)₃, Y(tBu₂FMD)₃, Y(tBu₂AMD)₃, Y(iPr₂FMD)₃, Y(iPr₂AMD)₃, YCp₂(iPr₂AMD), YCp₂(tBu₂AMD), YCp₂(iPr₂FMD), YCp₂(tBu₂FMD), Y(MeCp)₂(iPr₂AMD), Y(MeCp)₂(tBu₂AMD), Y(MeCp)₂(iPr₂FMD), Y(MeCp)₂(tBu₂FMD), Y(EtCp)₂(iPr₂AMD), Y(EtCp)₂(tBu₂AMD), Y(EtCp)₂(iPr₂FMD), Y(EtCp)₂(tBu₂FMD), Y(iPrCp)₂(iPr₂AMD), Y(iPrCp)₂(tBu₂AMD), Y(iPrCp)₂(iPr₂FMD), Y(iPrCp)₂(tBu₂FMD), Y(dmadmb)₃ and Y(pipdmb)₃.

Lanthanum precursors: In some embodiments, the lanthanum precursor is selected from the following: LaCp₃, La(MeCp)₃, La(EtCp)₃, La(iPrCp)₃, La(tBuCp)₃, La(TMSCp)₃, La(thd)₃, La(N(SiMe₃)₂)₃, La(iPr₂FMD)₃, La(tBu₂FMD)₃, La(sBu₂FMD)₃, La(tPn₂FMD)₃, La(iPr₂AMD)₃, La(tBu₂AMD)₃, La(sBu₂AMD)₃, La(tPn₂AMD)₃, LaCp₂(iPr₂AMD), LaCp₂(tBu₂AMD), LaCp₂(iPr₂FMD), LaCp₂(tBu₂FMD), La(MeCp)₂(iPr₂AMD), La(MeCp)₂(tBu2AMD), La(MeCp)₂(iPr₂FMD), La(MeCp)₂(tBu₂FMD), La(EtCp)₂(iPr₂AMD), La(EtCp)₂(tBu₂AMD), La(EtCp)₂(iPr₂FMD), La(EtCp)₂(tBu₂FMD), La(iPrCp)₂(iPr₂AMD), La(iPrCp)₂(tBu₂AMD), La(iPrCp)₂(iPr₂FMD), La(iPrCp)₂(tBu₂FMD), La(tBuCp)₂(iPr₂AMD), La(tBuCp)₂(tBu₂AMD), La(tBuCp)₂(iPr₂FMD), La(tBuCp)₂(tBu₂FMD) and La(pipdmb)₃.

Lutetium precursors: In some embodiments, the lutetium precursor is selected from the following: LuCp₃, Lu(MeCp)₃, Lu(EtCp)₃, Lu(iPrCp)₃, Lu(acac)₃, Lu(thd)₃, Lu(OiPr)₃, Lu(OtBu)₃, Lu(N(SiMe₃)₂)₃, Lu(Et₂FMD)₃, Lu(iPr₂FMD)₃, Lu(tBu₂FMD)₃, Lu(iPr₂AMD)₃, Lu(tBu₂AMD)₃, LuCp₂(iPr₂FMD), Lu(MeCp)₂(iPr₂FMD), Lu(EtCp)₂(iPr₂FMD), Lu(iPrCp)₂(iPr₂FMD), LuCp₂(iPr₂AMD), Lu(MeCp)₂(iPr₂AMD), Lu(EtCp)₂(iPr₂AMD), Lu(iPrCp)₂(iPr₂AMD), Lu(dmadmb)₃, La(pydmb)₃, and Lu(pipdmb)₃.

During the step of providing the threshold voltage tuning material reactant, a ligand of the treatment reactant on the treated surface can be removed, thereby removing any (e.g., carbon) contaminants that might otherwise remain.

As illustrated in FIG. 1, steps 106 and 108 can be repeated (110)—e.g., to form a desired thickness of the N-dipole shifting material layer. In some embodiments, subsequent deposition cycles are separated by an inter-deposition cycle purge. In some embodiments, the duration of the inter-deposition cycle purge is from at least 0.025 s to at most 2.0 s, or from at least 0.05 s to at most 0.8 s, or from at least 0.1 s to at most 0.4 s, or from at least 0.2 s to at most 0.3 s.

In some embodiments, a precursor pulse and an alcohol reactant pulse are separated by an intra-deposition cycle purge. In some embodiments, the duration of the intra-deposition cycle purge is from at least 0.025 s to at most 2.0 s, or from at least 0.05 s to at most 0.8 s, or from at least 0.1 s to at most 0.4 s, or from at least 0.2 s to at most 0.3 s.

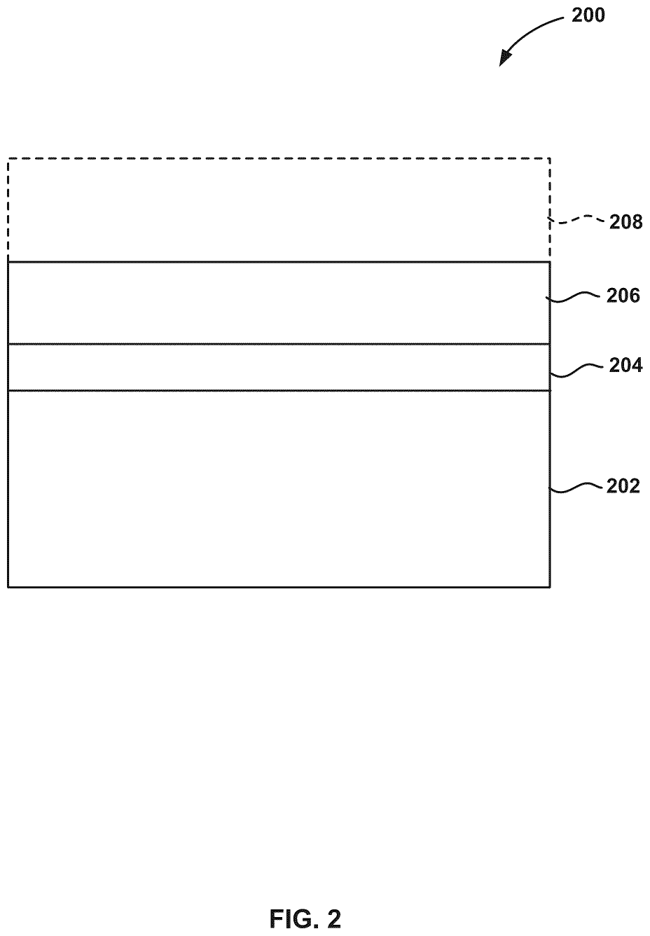

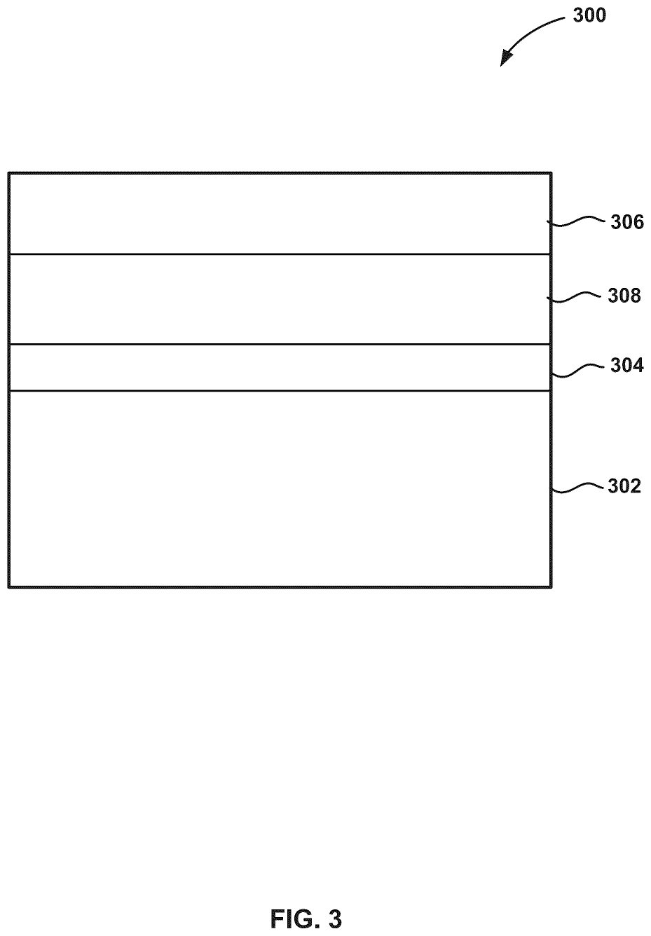

FIGS. 2 and 3 illustrate structures 200 and 300 formed in accordance with examples of the disclosure. For example, structures 200 and 300 can be formed using method 100.

Structure 200 includes a substrate 202, an oxide layer 204 (e.g., an interlayer dielectric (e.g., oxide, such as silicon oxide)), and an N-dipole shifting material layer 206. Structure 200 can also include a high-k dielectric material layer 208.

Substrate 202 can be as described above. Oxide layer 204 can be the same or similar to the oxide surface described above. N-dipole shifting material layer 206 can be formed according to method 100—e.g., using one or more cycles 110. By way of examples, N-dipole shifting material layer 206 can include a rare earth metal oxide, such as an oxide or one or more of Sc, Y, La, Ce, Pr, Nd, Pm, Sm, Eu, Gd, Tb, Dy, Ho, Er, Tm, Yb, and Lu. A thickness of N-dipole shifting material layer 206 can be less than 10 Å or less than 6 Å and/or greater than 1 Å or greater than 1.5 Å. High-k dielectric material layer 208 can be or include a metal oxide, such as, for example, hafnium oxide, zirconium oxide, hafnium zirconium oxide, or hafnium silicate. A thickness of high-k dielectric material layer 208 can be between about 5 and about 30 Angstroms or about 10 and about 15 Angstroms.

In the illustrated example, an N-dipole shifting material layer 206 is formed overlying and in contact with oxide layer 204. This structure is referred to as a dipole first structure.

Structure 300, illustrated in FIG. 3, can be used to form a dipole last or a dipole middle structure. Similar to structure 200, structure 300 includes a substrate 302, an oxide layer 304 (e.g., an interlayer dielectric (e.g., oxide, such as silicon oxide)), an N-dipole shifting material layer 306, and a high-k dielectric material layer 308. Compositions and thickness of layers 302-308 can be as described above in connection with FIG. 2. As illustrated, N-dipole shifting material layer 306 is formed overlying and in contact with high-k dielectric material layer 308, rather than oxide layer 304.

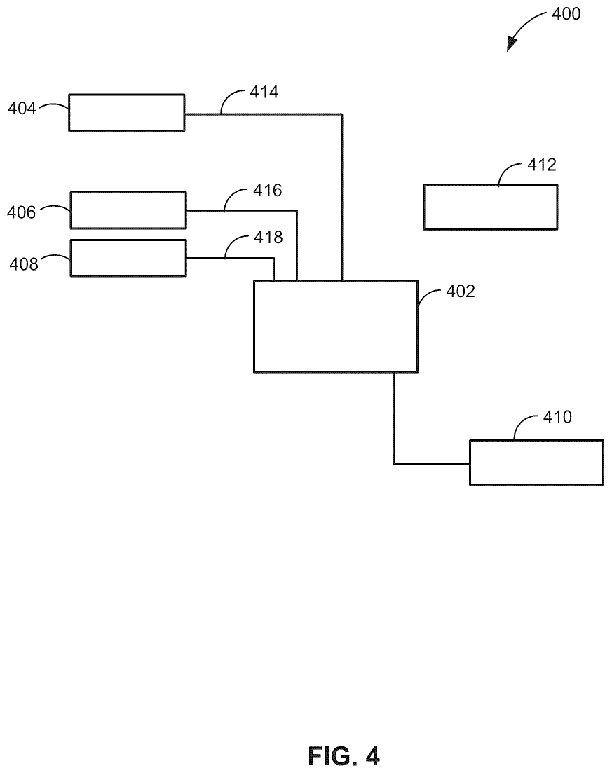

FIG. 4 illustrates a system 400 in accordance with yet additional exemplary embodiments of the disclosure. System 400 can be used to perform a method as described herein and/or form a structure or device portion as described herein.

In the illustrated example, system 400 includes one or more reaction chambers 402, a rare earth metal precursor source 404, an alcohol reactant 406, a purge gas and/or carrier gas source 408, an exhaust 410, and a controller 412.

Reaction chamber 402 can include any suitable reaction chamber, such as an ALD or CVD reaction chamber.

Rare earth metal precursor source 404 can include a vessel and one or more rare earth metal precursors as described herein—alone or mixed with one or more carrier (e.g., noble) gases. Alcohol reactant gas source 406 can include a vessel and one or more alcohol reactants as described herein—alone or mixed with one or more carrier gases. Purge gas source 408 can include one or more inert gases as described herein. Although illustrated with three gas sources 404-408, system 400 can include any suitable number of gas sources. Gas sources 404-408 can be coupled to reaction chamber 402 via lines 414-418, which can each include flow controllers, valves, heaters, and the like.

Exhaust 410 can include one or more vacuum pumps.

Controller 412 includes electronic circuitry and software to selectively operate valves, manifolds, heaters, pumps and other components included in system 400. Such circuitry and components operate to introduce precursors, reactants, and purge gases from the respective sources 404-408. Controller 412 can control timing of gas pulse sequences, temperature of the substrate and/or reaction chamber, pressure within the reaction chamber, and various other operations to provide proper operation of the system 400. Controller 412 can include control software to electrically or pneumatically control valves to control flow of precursors, reactants and purge gases into and out of the reaction chamber 402. Controller 412 can include modules, such as a software or hardware component, e.g., a FPGA or ASIC, which performs certain tasks. A module can advantageously be configured to reside on the addressable storage medium of the control system and be configured to execute one or more processes.

Other configurations of system 400 are possible, including different numbers and kinds of precursor and reactant sources and purge gas sources. Further, it will be appreciated that there are many arrangements of valves, conduits, precursor sources, and purge gas sources that may be used to accomplish the goal of selectively feeding gases into the reaction chamber 402. Further, as a schematic representation of a system, many components have been omitted for simplicity of illustration, and such components may include, for example, various valves, manifolds, purifiers, heaters, containers, vents, and/or bypasses.

During operation of reactor system 400, substrates, such as semiconductor wafers (not illustrated), are transferred from, e.g., a substrate handling system to reaction chamber 402. Once substrate(s) are transferred to reaction chamber 402, one or more gases from gas sources 404-408, such as precursors, reactants, carrier gases, and/or purge gases, are introduced into reaction chamber 402.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

1. A method of forming an N-dipole structure, the method comprising the steps of:
providing a substrate within a reaction chamber of a reactor;
depositing an N-dipole shifting material layer on the substrate using a cyclical deposition process comprising:
providing a rare earth metal precursor to the reaction chamber for a precursor pulse; and
providing an alcohol reactant to the reaction chamber,
wherein the alcohol reactant is an alcohol of the formula ROH, where R is a substituted or unsubstituted alkyl group comprising 1 to 12 carbon atoms or is a substituted or unsubstituted aryl group comprising 6 to 10 carbon atoms.

2. The method of claim 1, wherein the substituted or unsubstituted alkyl group comprises a straight chain, a branched chain, or a cyclic formation of carbon atoms.

3. The method of claim 1, wherein the substituted or unsubstituted alkyl group comprises a substituted alkyl group comprising one or more atoms selected from the list of N, O, F, Si, S, or Cl.

4. The method of claim 1, wherein the substituted or unsubstituted alkyl group comprises a carbon-carbon double bond or a carbon-carbon triple bond.

5. The method of claim 1, wherein the substituted or unsubstituted alkyl group is selected from methyl, ethyl, propyl, isopropyl, butyl, sec-butyl, isobutyl, tert-butyl, pentyl, 2-pentyl, 3-pentyl, tert-pentyl, cyclopentyl, hexyl, or cyclohexyl.

6. The method of claim 1, wherein the substituted or unsubstituted aryl group comprises a phenyl group.

7. The method of claim 1, wherein the substituted or unsubstituted aryl group comprises a phenyl group with one alkyl substituent.

8. The method of claim 1, wherein the substituted or unsubstituted aryl group comprises a toluyl group, a xylyl group, or a mesityl group.

9. The method of claim 1, wherein the alcohol reactant comprises one or more of methanol, ethanol, 1-propanol, isopropanol, 1-butanol, 2-butanol, isobutanol, tert-butanol, 1-pentanol, 1-hexanol, cyclohexanol, or phenol.

10. The method of claim 1, wherein the rare earth metal precursor comprises one or more elements selected from the group consisting of Sc, Y, La, Ce, Pr, Nd, Pm, Sm, Eu, Gd, Tb, Dy, Ho, Er, Tm, Yb, and Lu.

11. The method of claim 1, wherein the rare earth metal precursor comprises one or more cyclopentadienyl ligands.

12. The method of claim 1, wherein the rare earth metal precursor comprises one or more amido ligands.

13. The method of claim 1, wherein the rare earth metal precursor comprises one or more amidinate ligands.

14. The method of claim 1, wherein the rare earth metal precursor comprises one or more alkoxide ligands.

15. The method of claim 1, wherein the rare earth metal precursor comprises one or more enaminolate ligands.

16. The method of claim 1, wherein the rare earth metal precursor comprises one or more diketonate ligands.

17. The method of claim 1, wherein the rare earth metal precursor comprises one or more of ScCp₃, Sc(MeCp)₃, Sc(EtCp)₃, Sc(iPrCp)₃, Sc(acac)₃, Sc(thd)₃, Sc(N(SiMe₃)₂)₃, Sc(Et₂AMD)₃, Sc(iPr₂FMD)₃, Sc(iPr₂AMD)₃, Sc(tBu₂FMD)₃, Sc(tBu₂AMD)₃, ScCp₂(iPr₂FMD), Sc(MeCp)₂(iPr₂FMD), Sc(EtCp)₂(iPr₂FMD), Sc(iPrCp)₂(iPr₂FMD), ScCp₂(iPr₂AMD), Sc(MeCp)₂(iPr₂AMD), Sc(EtCp)₂(iPr₂AMD), or Sc(iPrCp)₂(iPr₂AMD).

18. The method of claim 1, wherein the rare earth metal precursor comprises one or more of YCp₃, Y(MeCp)₃, Y(EtCp)₃, Y(iPrCp)₃, Y(tBuCp)₃, Y(thd)₃, Y(N(SiMe₃)₂)₃, Y(tBu₂FMD)₃, Y(tBu₂AMD)₃, Y(iPr₂FMD)₃, Y(iPr₂AMD)₃, YCp₂(iPr₂AMD), YCp₂(tBu₂AMD), YCp₂(iPr₂FMD), YCp₂(tBu₂FMD), Y(MeCp)₂(iPr₂AMD), Y(MeCp)₂(tBu₂AMD), Y(MeCp)₂(iPr₂FMD), Y(MeCp)₂(tBu₂FMD), Y(EtCp)₂(iPr₂AMD), Y(EtCp)₂(tBu₂AMD), Y(EtCp)₂(iPr₂FMD), Y(EtCp)₂(tBu₂FMD), Y(iPrCp)₂(iPr₂AMD), Y(iPrCp)₂(tBu₂AMD), Y(iPrCp)₂(iPr₂FMD), Y(iPrCp)₂(tBu₂FMD), Y(dmadmb)₃, or Y(pipdmb)₃.

19. The method of claim 1, wherein the rare earth metal precursor comprises one or more of LaCp₃, La(MeCp)₃, La(EtCp)₃, La(iPrCp)₃, La(tBuCp)₃, La(TMSCp)₃, La(thd)₃, La(N(SiMe₃)₂)₃, La(iPr₂FMD)₃, La(tBu₂FMD)₃, La(sBu₂FMD)₃, La(tPn₂FMD)₃, La(iPr₂AMD)₃, La(tBu₂AMD)₃, La(sBu₂AMD)₃, La(tPn₂AMD)₃, LaCp₂(iPr₂AMD), LaCp₂(tBu₂AMD), LaCp₂(iPr₂FMD), LaCp₂(tBu₂FMD), La(MeCp)₂(iPr₂AMD), La(MeCp)₂(tBu2AMD), La(MeCp)₂(iPr₂FMD), La(MeCp)₂(tBu₂FMD), La(EtCp)₂(iPr₂AMD), La(EtCp)₂(tBu₂AMD), La(EtCp)₂(iPr₂FMD), La(EtCp)₂(tBu₂FMD), La(iPrCp)₂(iPr₂AMD), La(iPrCp)₂(tBu₂AMD), La(iPrCp)₂(iPr₂FMD), La(iPrCp)₂(tBu₂FMD), La(tBuCp)₂(iPr₂AMD), La(tBuCp)₂(tBu₂AMD), La(tBuCp)₂(iPr₂FMD), La(tBuCp)₂(tBu₂FMD), or La(pipdmb)₃.

20. A method of forming a dipole first structure comprising the method of claim 1.
